(19) United States
(12) Patent Application Publication
(10) Pub. No.: US 2025/0216452 A1
(43) Pub. Date: Jul. 3, 2025

(54) DEVICE TESTING SYSTEM AND DEVICE TESTING METHOD

(71) Applicant: Getac Technology Corporation, New Taipei City (TW)

(72) Inventor: Chien-Chih HU, Taipei City (TW)

(21) Appl. No.: 18/908,945

(22) Filed: Oct. 8, 2024

(30) Foreign Application Priority Data
Dec. 27, 2023 (TW) 112151172

(51) Int. Cl. G01R 31/317; G01R 31/3181

(52) U.S. Cl. CPC G01R 31/31701; G01R 31/31725; G01R 31/31813

(57) ABSTRACT

A device testing method, including: transmitting, by a server, test data to a device under test, wherein the test data includes a test time and a test instruction, and the test instruction corresponds to a unit under test in the device under test; determining, by the device under test, whether a system time of the device under test corresponds to the test time; and when the system time corresponds to the test time, controlling the unit under test according to the test instruction and recording a test result of the unit under test executing the test instruction.

### CROSS-REFERENCE TO RELATED APPLICATION

This application claims priority to Taiwan Application Serial Number 112151172, filed Dec. 27, 2023, which is herein incorporated by reference in its entirety.

### BACKGROUND

### Technical Field

The present disclosure relates to a testing technology, more particularly a device testing system and a device testing method.

### Description of Related Art

With the rapid development of microelectronics technology and network communication, electronic devices with various purposes are widely used in daily life. Generally speaking, electronic devices include multiple software or hardware with multiple different functions to perform corresponding functions respectively, such as a network communication module for data transmission, a battery management module for power management, a display screen for presenting images. If some functions are abnormal, it may also affect the normal operation of the electronic device. In order to prevent electronic devices from causing inconvenience to users due to a sudden abnormality, regular testing and maintenance of electronic devices has become a necessary step.

### SUMMARY

One aspect of the present disclosure is a device testing method, including: transmitting, by a server, test data to a device under test, wherein the test data includes a test time and a test instruction, and the test instruction corresponds to a unit under test in the device under test; determining, by the device under test, whether a system time of the device under test corresponds to the test time; and when the system time corresponds to the test time, controlling the unit under test according to the test instruction and recording a test result of the unit under test executing the test instruction.

Another aspect of the present disclosure is a device testing system, including a device under test and a server. The device under test includes a processing unit, a unit under test, and a memory unit. The server is communicatively connected to the device under test and is configured to transmit a test data to the device under test. The test data includes a test time and a test instruction, and the test instruction corresponds to the unit under test. The device under test is configured to set a test event according to the test time and is configured to store the test instruction in the memory unit. When the test event is triggered, the processing unit is configured to control the unit under test according to the test instruction and record a test result of the unit under test executing the test instruction.

It is to be understood that both the foregoing general description and the following detailed description are by examples and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a device testing system in some embodiments of the present disclosure.

FIG. 2 is a flowchart illustrating a device testing method in some embodiments of the present disclosure.

### DETAILED DESCRIPTION

While the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element is referred to as being “directly connected” or “directly coupled” to another element, there are no intervening elements present. As used herein, the term “and/or” includes associated listed items or any and all combinations of more.

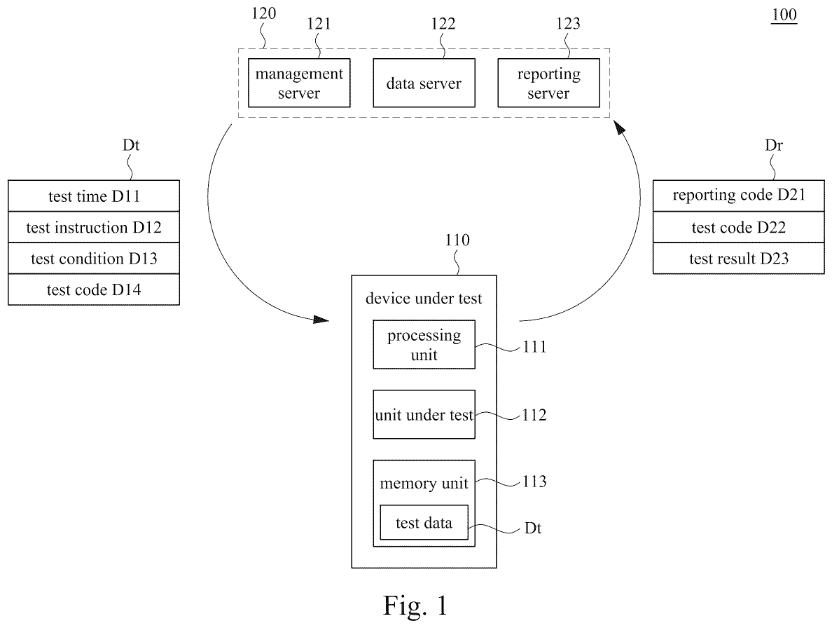

FIG. 1 is a schematic diagram of a device testing system 100 in some embodiments of the present disclosure. The device testing system 100 includes at least one device under test 110 and a server 120. The device under test 110 can be any type of electronic device, such as smartphones, personal computers, industrial machines, smart home appliances, wearable devices, network equipment, and/or electronic instruments. The server 120 can be a host server of an enterprise that produces/sells/provides the device under test 110, stores relevant information about the device under test 110 (e.g., product model or product code), and records the functions of each device under test 110.

As shown in FIG. 1, in some embodiments, the device under test 110 includes a processing unit 111, a unit under test 112, and a memory unit 113. The processing unit 111 can be a processing circuit, and is configured to perform various operations. The processing unit 111 includes but is not limited to a single processor or the integration of multiple microprocessors. The processing unit 111 may be implemented as a central processing unit (CPU), a system on chip (SoC), an application processor, a digital signal processor, or a processing chip or controller with specific functions.

The unit under test 112 can be a circuit, a hardware element, a software program, firmware, or a module that performs a specific function. The unit under test 112 is coupled to the processing unit 111. When the processing unit 111 drives/activates the unit under test 112, the processing unit 111 obtains or detects an operating status of the unit under test 112, or obtains data generated when the unit under test 112 is operating. For example, if the unit under test 112 is a network communication circuit or a network communication program, the processing unit 111 obtains the operating status of the unit under test 112 (e.g., size of data transfer or length of response time), or determines whether there is an abnormality (e.g., data downloading and data uploading are not equivalent or the response time is too long).

It should be mentioned here that although there is only one unit under test 112 shown in FIG. 1, the number of the unit under test 112 is not limited to one. In some other embodiments, the device under test 110 may have multiple program/software, hardware, or functions that need to be tested, so the device under test 110 includes multiple different units under test 112.

The memory unit 113 is coupled to the processing unit 111, and is configured to store test data Dt required during testing. The content of the test data Dt will be explained in the subsequent paragraphs. The memory unit 113 may include but is not limited to flash memory, hard disk (HDD), solid state drive (SSD), dynamic random access memory (DRAM), static random access memory (SRAM), or non-transitory computer-readable media.

The server 120 is communicatively connected to the device under test 110, and the server 120 is configured to transmit the test data Dt to the device under test 110 and receive a test result transmitted by the device under test 110. In one embodiment, the server 120 includes a management server 121, a data server 122, and a reporting server 123. The management server 121, the data server 122, and the reporting server 123 are communicatively connected to each other and are configured to execute different operations. However, in some other embodiments, the management server 121, the data server 122, and the reporting server 123 can also be integrated into the same host server.

The device testing system 100 is configured to test the device under test 110, so as to determine whether the operation of each unit under test 112 in the device under test 110 is as expected. Although a tester can manually operate the device under test 110 to test the unit under test 112, the efficiency of this method is too low. In addition, it is also necessary to consider whether the current status of each device under test 110 is suitable for testing. For example, when testing network connectivity, if a user is using network services of the device under test 110 at the same time, the quality of network services or the accuracy of the test may be affected. In other words, during testing, the unit under test 112 needs to temporarily stop performing operations other than testing.

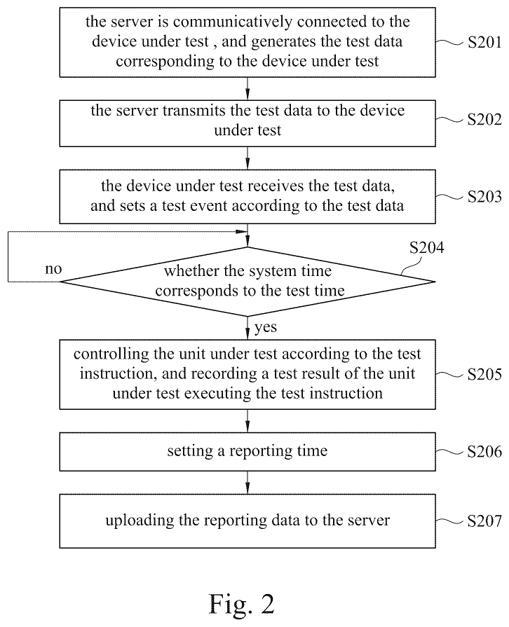

FIG. 2 is a flowchart illustrating a device testing method in some embodiments of the present disclosure. Referring to FIG. 1 and FIG. 2, in step S201, when starting testing, the server 120 is communicatively connected to the device under test 110, and the server 120 generates the test data Dt corresponding to the device under test 110. In one embodiment, each of the test data Dt corresponds to one unit under test 112 of the device under test 110. Therefore, in order to test multiple functions at the same time, the server 120 will generate multiple test data Dt corresponding to multiple units under test 112.

Specifically, when the device under test 110 connects to the management server 121, the management server 121 identifies a device code of the device under test 110. The data server 122 stores different types of the device code and corresponding device functions in advance. Therefore, the management server 121 can obtain one or more functions under test of the unit(s) under test 112 corresponding to the device under test 110 through the data server 122 according to the device code(s), and the management server 121 generates the test data Dt accordingly.

For example, when the management server 121 determines that the device under test 110 includes multiple units under test 112 and multiple corresponding functions under test (e.g., network function, temperature detection function, and/or alarm sound function), the management server 121 organizes these functions under test into a selection list and transmits the selection list to the device under test 110 (e.g., a table that includes multiple options is presented on the display screen for checking). Then, the user operates the device under test 110 to select/check one or more selection items (e.g., corresponding to the units under test 112 or the functions under test) in the selection list. The device under test 110 returns a selection result to the management server 121, so that the management server 121 generates the test data Dt.

In step S202, the server 120 transmits the test data Dt to the device under test 110. The test data Dt includes a test time D11 and a test instruction D12. “Test time D11” is configured to indicate a time executing test, which can be a specific time (e.g., 9 p.m.) or a period of time (e.g., 8 hours later). “Test instruction D12” an instruction configured to control the unit under test 112 (e.g., recording a response time of processing data packets or recording an update rate of the display screen).

In some other embodiments, the test data Dt further includes a test condition D13. “Test condition D13” indicates the operating status of the device under test 110 or the unit under test 112. For example, the test condition D13 can be “the unit under test 112 does not execute event instructions other than testing”, “the current load of the processing unit 111 does not exceed 60%”, or “whether the power of the device under test 110 is higher than a preset value”.

In other embodiments, the test data Dt further includes a test code D14. “Test code D14” can be a test serial number generated by the management server 121 for the device under test 110 or the unit under test 112, and the device code of the device under test 110 also can be used as the test code D14.

In one embodiment, the test data Dt further includes a trigger program. In other words, the test data Dt can be stored in the memory unit 113 in the form of the trigger program, so that the processing unit 111 will automatically or sequentially obtain multiple control instructions to control the unit under test 112 to complete subsequent steps S203-S207 after executing the trigger program. The trigger program can be part or all of the test data Dt. For example, the test instruction D12 and the test condition D13 can be organized into the trigger program.

In step S203, the device under test 110 receives the test data Dt from the management server 121 and sets a test event according to the test data Dt, so as to store the test instruction D12 into the memory unit 113. Setting the test event means the processing unit 111 registers a trigger event in the system, wherein the trigger time is the test time D11, and the execution content is the test instruction D12. In one embodiment, the method of “setting the test event” includes storing part or all of the test data Dt in the memory unit 113. Therefore, when the system time corresponds to the test time D11, the processing unit 111 will automatically execute the test instruction D12.

in some embodiments, when the device under test 110 receives the test data Dt, the device under test 110 can determine whether another test event is set in the memory unit 113 according to the test code D14 of the test data Dt, so as to determine whether there are conflicts or duplications between multiple the test events. Specifically, if the processing unit 111 determines another test event is set in the memory unit 113, and the test code of “the test event that has been set” is equal to the test code D14 of “the test data Dt currently received”, it means that the target to be tested by the two test events is the same. At this time, the processing unit 111 will clear/delete the test event that has been set in the memory unit 113 and use the currently received test data Dt to reset and set a new test event.

In step S204, after the device under test 110 sets the test event according to the test data Dt, the device under test 110 determines whether the system time corresponds to the test time D11. If the system time corresponds to the test time D11, the test event will be triggered automatically.

In step S205, when the system time corresponds to the test time D11, the test event is triggered automatically. At this time, the processing unit 111 controls the unit under test 112 according to the test instruction D12, so that the unit under test 112 executes the corresponding operation, and the processing unit 111 records a test result of the unit under test 112 executing the test instruction D12. In some embodiments, the processing unit 111 can monitor the operating status of the unit under test 112 or receive data generated by the unit under test 112.

Specifically, the method of executing the test event by the processing unit 111 includes the following: driving the unit under test 112 according to the test instruction D12 and, during the unit under test 112, executing the test instruction D12 and receiving and organizing data generated by the unit under test 112 as the test result. Then, organizing the test result as reporting data Dr. As shown in FIG. 1, in some embodiments, the processing unit 111 generates the reporting data Dr according to the test result and the test data Dt. The reporting data Dr includes a reporting code D21, a test code D22 (can be the same as the test code D14 in the test data Dt) and a test result D23. The reporting code D21 can be a serial number generated by the processing unit 111 or can be distributed by the server 120 to the test data Dt. The reporting code D21 can correspond to the test code D14.

In some embodiments, when the system time corresponds to the test time D11, the processing unit 111 can determine whether the operating status of the device under test 110 (or the unit under test 112) satisfies the test condition D13 of the test data Dt when the test event is triggered (e.g., after triggering, but before performing the operation). For example, determining whether the device under test 110 is currently sleeping, determining whether the current load of the processing unit 111 satisfies expectations, determining whether the unit under test 112 is currently executing some event instructions, and/or determining whether the power of the device under test 110 is sufficient. When determining whether the operating status of the device under test 110 or the unit under test 112 satisfies the test condition D13, the processing unit 111 controls the unit under test 112 to execute the test instruction D12.

When the system time corresponds to the test time D11, if the processing unit 111 determines the operating status of the device under test 110 or the unit under test 112 does not satisfy the test condition D13, the processing unit 111 will reset the test event and delay the trigger time of the test event by a delay interval (e.g., one hour or 24 hours) to set a check time. In other words, setting the check time to the test time plus the delay interval.

For example, the original test time D11 is “9 p.m.” and the delay interval is “1 hour”. When the system time is 9 pm, but the operating status of the unit under test 112 does not satisfy the test condition D13, the processing unit 111 sets “10 p.m.” as the check time, that is, the test event will be retriggered at 10 p.m. “Delay interval” may be included in the test data Dt provided by the server 120 to the device under test 110 or may be set by the device under test 110 itself.

Similarly, when the system time corresponds to the check time again, the processing unit 111 determines whether the operating status of the device under test 110 or the unit under test 112 satisfies the test condition D13 again. If the operating status satisfies the test condition D13, the processing unit 111 controls the unit under test 112 to execute the test instruction D12. If the operating status still does not satisfy the test condition D13, the processing unit 111 can delay the check time by the delay interval again to set a new check time.

In step S206, after the processing unit 111 executes the test instruction D12 and generates the reporting data Dr, the processing unit 111 sets a reporting time (e.g., one hour later) as a time for uploading the reporting data Dr. In some other embodiments, the processing unit 111 can upload the reporting data Dr immediately after generating the reporting data Dr without setting the reporting time.

In step S207, when the system time corresponds to the reporting time, if the processing unit 111 determines the device under test 110 is communicatively connected to the reporting server 123, the processing unit 111 uploads the reporting data Dr to the reporting server 123. At this time, the reporting server 123 identifies the device under test 110 according to the test code D22 of the reporting data Dr and stores the reporting data Dr into the data server 122.

The device testing method enables the server 120 to test a large number of the devices under test and efficiently record the test results of all devices under test in the data server 122 to facilitate management and maintenance of the status of the devices under test. Since the present disclosure stores the test data Dt in the device under test 110 and allowing the device under test 110 to trigger the test event by itself, executing the test event will not increase the load of the server 120, and the user does not need to operate manually, greatly improving convenience.

On the other hand, the device under test 110 sets the test event according to the test time D11 and the test condition D13 of the test data Dt. Therefore, the test event will automatically avoid the time when the user frequently uses the device under test 110 or automatically avoids the time when the device under test 110 is underpowered or overloaded, to ensure that the user's use of the device under test 110 will not be affected.

In addition, since the device under test 110 tests the unit under test 112 on its own according to the test data Dt, after the device under test 110 sets the test event, the device under test 110 does not need to maintain a communication connection with the server 120, thus improving the flexibility during testing.

The elements, method steps, or technical features in the foregoing embodiments may be combined with each other and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A device testing method, comprising:
transmitting, by a server, test data to a device under test, wherein the test data comprises a test time and a test instruction, and the test instruction corresponds to a unit under test in the device under test;
determining, by the device under test, whether a system time of the device under test corresponds to the test time; and
when the system time corresponds to the test time, controlling the unit under test according to the test instruction and recording a test result of the unit under test executing the test instruction.

2. The device testing method of claim 1, wherein the test data further comprises a test condition, and controlling the unit under test according to the test instruction comprises:
when the system time corresponds to the test time, determining whether an operating status of the device under test satisfies the test condition, wherein when the operating status satisfies the test condition, the unit under test executes the test instruction.

3. The device testing method of claim 2, wherein controlling the unit under test according to the test instruction further comprises:
when the operating status does not satisfy the test condition, setting a check time; and
when the system time corresponds to the check time, determining whether the operating status of the device under test satisfies the test condition again, wherein when the operating status satisfies the test condition, the unit under test executes the test instruction.

4. The device testing method of claim 3, wherein the test data further comprises a delay interval, and setting the check time comprises:
setting the check time to the test time plus the delay interval.

5. The device testing method of claim 2, wherein determining whether the operating status of the device under test satisfies the test condition comprises:
determining whether the device under test is executing an event instruction.

6. The device testing method of claim 2, wherein determining whether the operating status of the device under test satisfies the test condition comprises:
determining whether the device under test is communicatively connected to the server.

7. The device testing method of claim 1, wherein the test data further comprises a trigger program, and controlling the unit under test according to the test instruction comprises:
executing the trigger program to control the unit under test to execute the test instruction, wherein the unit under test is a program or a circuit of the device under test.

8. The device testing method of claim 1, further comprising;
identifying, by the server, a device code of the device under test;
obtaining a plurality of functions under test corresponding to the device under test according to the device code; and
generating the test data according to the plurality of functions under test.

9. The device testing method of claim 8, wherein generating the test data comprises;
transmitting a selection list to the device under test according to the plurality of functions under test; and
generating the test data according to a selection item selected by the device under test in the selection list.

10. The device testing method of claim 1, wherein the test data further comprises a test code, and the device testing method further comprises:
storing, by the device under test, the test data;
determining whether another test code is stored in the device under test; and
when the another test code is equal to the test code, resetting a test event according to the test time of the test data.

11. A device testing system, comprising:
a device under test comprising a processing unit, a unit under test, and a memory unit; and
a server communicatively connected to the device under test and configured to transmit test data to the device under test, wherein the test data comprises a test time and a test instruction, and the test instruction corresponds to the unit under test;
wherein the device under test is configured to set a test event according to the test time and is configured to store the test instruction in the memory unit;
wherein when the test event is triggered, the processing unit is configured to control the unit under test according to the test instruction and record a test result of the unit under test executing the test instruction.

12. The device testing system of claim 11, wherein the test data further comprises a test condition, and when a system time corresponds to the test time, the processing unit is configured to determine whether an operating status of the device under test satisfies the test condition.

13. The device testing system of claim 12, wherein when the system time corresponds to the test time and the operating status does not satisfy the test condition, the processing unit is configured to delay the test event by a delay interval to set a check time; and
wherein when the system time corresponds to the test time and the operating status satisfies the test condition, the processing unit is configured to control the unit under test to execute the test instruction.

14. The device testing system of claim 13, wherein the test data further comprises the delay interval.

15. The device testing system of claim 12, wherein when the system time corresponds to the test time, the processing unit is configured to determine whether the device under test is executing an event instruction.

16. The device testing system of claim 12, wherein when the system time corresponds to the test time, the processing unit is configured to determine whether the device under test is communicatively connected to the server.

17. The device testing system of claim 11, wherein the test data further comprises a trigger program, the processing unit is configured to execute the trigger program to control the unit under test execute the test instruction, and the unit under test is a program or a circuit of the device under test.

18. The device testing system of claim 11, wherein the server is configured to identify a device code of the device under test to obtain a plurality of functions under test corresponding to the device under test according to the device code, and the server is further configured to generate the test data according to the plurality of functions under test.

19. The device testing system of claim 18, wherein the server is configured to transmit a selection list to the device under test according to the plurality of functions under test and is configured to generate the test data according to a selection item selected by the device under test in the selection list.

20. The device testing system of claim 11, wherein the test data further comprises a test code, and when the device under test receives the test data, the processing unit is configured to determine whether another test event is set in the device under test; and
wherein when the another test event is set in the device under test and another test code of the another test event is equal to the test code of the test event, the processing unit is configured to delete the another test event and reset the test event.
